(19) United States
(12) Patent Application Publication
(10) Pub. No.: US 2026/0068719 A1
(43) Pub. Date: Mar. 5, 2026

(54) SEMICONDUCTOR PACKAGE

(71) Applicant: Samsung Electronics Co., Ltd., Suwon-si (KR)

(72) Inventors: Changyeon SONG, Suwon-si (KR); Dongwon KANG, Suwon-si (KR); Jaeean LEE, Suwon-si (KR)

(73) Assignee: Samsung Electronics Co., Ltd., Suwon-si (KR)

(21) Appl. No.: 19/291,852

(22) Filed: Aug. 6, 2025

(30) Foreign Application Priority Data
Aug. 27, 2024 (KR) 10-2024-0115254

(51) Int. Cl. H01L 23/498

(52) U.S. Cl. CPC H01L 23/49838

(57) ABSTRACT

A semiconductor package includes a lower redistribution structure; a connection structure on the lower redistribution structure and defining a cavity; a semiconductor chip on the lower redistribution structure and in the cavity; and an upper redistribution structure above the connection structure and the semiconductor chip and electrically connected to the connection structure, wherein the upper redistribution structure includes an upper insulating layer and an upper redistribution pattern; an upper connection pad on a top surface of the upper insulating layer, the upper connection pad being electrically connected to the upper redistribution pattern, including a horizontal portion and a vertical portion, and having a bowl shape; a metal pad on the horizontal portion and apart from an inner side surface of the vertical portion; and an upper passivation layer on the top surface of the upper insulating layer and defining an opening exposing a portion of the metal pad.

### CROSS-REFERENCE TO RELATED APPLICATION

This application is based on and claims priority under 35 U.S. C. § 119 to Korean Patent Application No. 10-2024-0115254, filed on Aug. 27, 2024, in the Korean Intellectual Property Office, the disclosure of which is incorporated by reference herein in its entirety.

### BACKGROUND

The inventive concepts relate to a semiconductor package, for example to a package-on-package-type semiconductor package.

With the increase in storage capacity of semiconductor chips, it may be advantageous for semiconductor packages including one or more semiconductor chips to be thin and light. There has been research into including semiconductor chips having various functions in a semiconductor package, such that the semiconductor chips operate relatively quickly. In accordance with this research, there has been active research into package-on-package type semiconductor packages having a structure in which an upper semiconductor package is mounted on a lower semiconductor package.

### SUMMARY

The inventive concepts relate a semiconductor package having increased reliability by allowing for prevention or reduction of the occurrence and/or magnitude of cracks between an upper connection pad and an upper passivation layer.

The inventive concepts are not limited to those mentioned above, and inventive concepts that have not been mentioned will be clearly understood by one of ordinary skill in the art from the description below.

According to some example embodiments of the inventive concepts, a semiconductor package may include a lower redistribution structure; a connection structure on the lower redistribution structure and defining a cavity; a semiconductor chip on the lower redistribution structure and in the cavity defined by the connection structure; and an upper redistribution structure above the connection structure and the semiconductor chip and electrically connected to the connection structure, wherein the upper redistribution structure includes an upper insulating layer and an upper redistribution pattern; an upper connection pad on a top surface of the upper insulating layer, the upper connection pad being electrically connected to the upper redistribution pattern, including a horizontal portion and a vertical portion, and having a bowl shape; a metal pad on the horizontal portion of the upper connection pad and apart from an inner side surface of the vertical portion of the upper connection pad; and an upper passivation layer on the top surface of the upper insulating layer and defining an opening exposing a portion of the metal pad.

According to some example embodiments of inventive concepts, a semiconductor package may include a lower redistribution structure; a connection structure on the lower redistribution structure and having defining a cavity, the connection structure including a via structure; a semiconductor chip arranged on the lower redistribution structure and in the cavity of defined by the connection structure; a molding layer at least partially filling a space defined between the connection structure and the semiconductor chip, in the cavity; and an upper redistribution structure arranged on the molding layer, and above the connection structure and the semiconductor chip, and electrically connected to the connection structure, wherein the upper redistribution structure includes an upper insulating layer and an upper redistribution pattern; an upper connection pad arranged on a top surface of the upper insulating layer and electrically connected to the upper redistribution pattern, the upper connection pad including a horizontal portion and a vertical portion, the vertical portion extending in a vertical direction on an edge of the horizontal portion in a vertical direction along an edge of the horizontal portion, the upper connection pad having a bowl shape, having an inner space defined by an inner side surface of the vertical portion and a top surface of the horizontal portion defining an inner space; a metal pad arranged in the inner space of the upper connection pad, and arranged on the top surface of the horizontal portion so as to be apart from the inner side surface of the vertical portion, the metal pad including a first metal pad and a second metal pad, the second metal pad on the first metal pad; and an upper passivation layer on the top surface of the upper insulating layer, and the upper passivation layer having defining an opening exposing a portion of the metal pad and having a horizontal width less than a horizontal width of the metal pad, wherein the upper passivation layer at least partially surrounds the inner side surface of the connection pad, an outer side surface of the connection pad, and a top surface of the vertical portion of the upper connection pad.

According to some example embodiments the inventive concepts, a semiconductor package may include a lower redistribution structure; a connection structure on the lower redistribution structure and having defining a cavity; a semiconductor chip arranged on the lower redistribution structure and in the cavity of defined by the connection structure; and an upper redistribution structure arranged above the connection structure and the semiconductor chip and electrically connected to the connection structure, wherein the upper redistribution structure includes an upper insulating layer and an upper redistribution pattern; an upper connection pad on a top surface of the upper insulating layer, the upper connection pad being electrically connected to the upper redistribution pattern, including a horizontal portion and a vertical portion, and having a bowl shape; a metal pad on the horizontal portion of the upper connection pad and in contact with an inner side surface of the vertical portion of the upper connection pattern; and an upper passivation layer arranged on the top surface of the upper insulating layer and having defining an opening exposing a portion of the metal pad.

### BRIEF DESCRIPTION OF THE DRAWINGS

Example embodiments will be more clearly understood from the following detailed description taken in conjunction with the accompanying drawings in which:

FIG. 1 is a schematic cross-sectional view of a semiconductor package according to some example embodiments;

FIG. 2 is a schematic enlarged view of region EX1 in FIG. 1;

FIG. 3 is a schematic cross-sectional view of a semiconductor package according to some example embodiments;

FIG. 4 is a schematic enlarged view of region EX2 in FIG. 3;

FIGS. 5 to 8 are diagrams illustrating sequential processes in a method of manufacturing a semiconductor package according to some example embodiments; and FIGS. 9 to 20 are enlarged views of region EX1 of the semiconductor package of FIG. 1 in sequential processes in a method of manufacturing the semiconductor package.

### DETAILED DESCRIPTION

Hereinafter, example embodiments are described in detail with reference to the accompanying drawings. In the drawing, like reference characters denote like elements, and redundant descriptions thereof will be omitted.

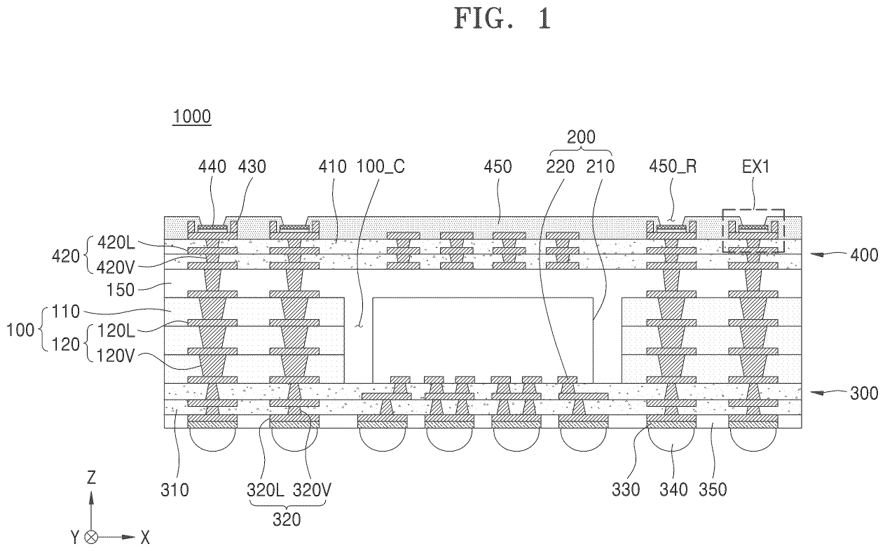

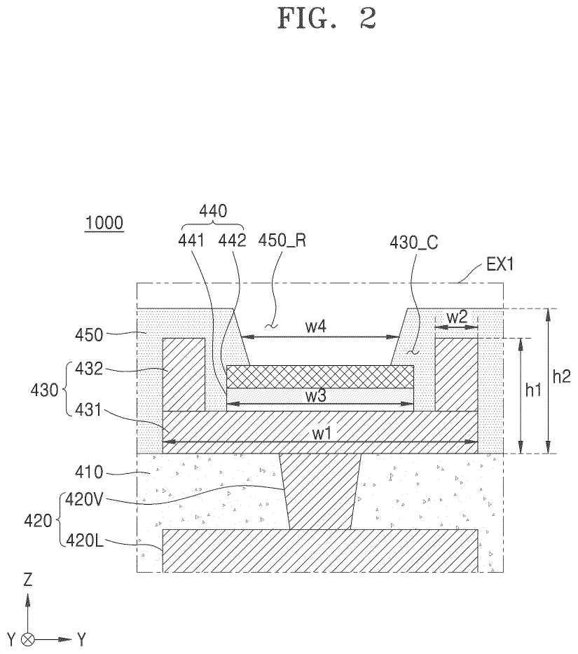

FIG. 1 is a schematic cross-sectional view of a semiconductor package 1000 according to some example embodiments. FIG. 2 is a schematic enlarged view of region EX1 in FIG. 1.

Referring to FIGS. 1 and 2, the semiconductor package 1000 may include a lower redistribution structure 300, a connection structure 100, a semiconductor chip 200, a molding layer 150, and an upper redistribution structure 400.

Hereinafter, unless particularly defined, a direction parallel with the top surface of the lower redistribution structure 300 is defined as a first horizontal direction (an X direction, a direction perpendicular to the top surface of the lower redistribution structure 300 is defined as a vertical direction (a Z direction), and a direction perpendicular to the first horizontal direction (the X direction) and the vertical direction (the Z direction) is defined as a second horizontal direction (a Y direction).

The connection structure 100 of the semiconductor package 1000 may be disposed on the lower redistribution structure 300. For example, the connection structure 100 may be electrically connected to a portion of a lower redistribution pattern 320 of the lower redistribution structure 300. The connection structure 100 may electrically connect the upper redistribution structure 400 to the lower redistribution structure 300.

The connection structure 100 may include (for example, define or at least partially define) a cavity 100_C extending (for example, defined to extend or as extending) from the top surface to the bottom surface thereof. The semiconductor chip 200 may be arranged in the cavity 100_C of the connection structure 100 (for example, between sidewalls of the connection structure 100 defining or at least partially defining cavity 100_C). Although it is illustrated in FIG. 1 that the cavity 100_C may be formed (for example, defined) in a central portion of the connection structure 100, the number and arrangement of cavities of cavity 100_C are not limited thereto.

The connection structure 100 may include a plurality of base layers 110 and a via structure 120. In some example embodiments, the base layers 110 may include, for example, first to third base layers stacked in the vertical direction (the Z direction). For example, the connection structure 100 may have a multi-layer structure including the first to third base layers. The base layers 110 may surround or at least partially surround at least a portion of the via structure 120.

In some example embodiments, any or each of the base layers 110 may include, for example, phenol resin, thermosetting resin such as epoxy, thermoplastic resin such as polyimide, and/or an insulating material in which a core including an inorganic filler and/or glass fiber is impregnated with at least one of phenol resin, thermosetting resin, or thermoplastic resin, but example embodiments are not limited thereto.

For example, each of the base layers 110 may include, for example, prepreg, an Ajinomoto build-up film (ABF), flame retardant 4 (FR-4), tetrafunctional epoxy, polyphenylene ether, bismaleimide triazine (BT), epoxy/polyphenylene oxide, thermount, cyanate ester, polyimide, liquid crystal polymer, or a combination thereof, but example embodiments are not limited thereto.

The via structure 120 may include a plurality of connection pads 120L and a plurality of connection vias 120V. The connection pads 120L may extend in the horizontal direction (the X direction and/or the Y direction) on the top or bottom surface of each of the base layers 110.

In some example embodiments, the connection pads 120L may include, for example, first to fourth connection pads at different vertical levels, but example embodiments are not limited thereto. The first connection pads at the bottom among the connection pads 120L may be connected to the lower redistribution structure 300. The fourth connection pads at the top among the connection pads 120L may be connected to the upper redistribution structure 400.

The connection vias 120V may extend in the vertical direction (the Z direction) within the base layers 110. The connection vias 120V may connect the connection pads 120L at different vertical levels to each other. In some example embodiments, the connection vias 120V may include, for example, first to third connection vias at different vertical levels, but example embodiments are not limited thereto.

In some example embodiments, any or each of the connection pads 120L may include, for example, electrolytically deposited copper foil, rolled-annealed copper foil, stainless steel foil, aluminum foil, ultra-thin copper foil, sputtered copper, and/or a copper alloy, but example embodiments are not limited thereto.

In some example embodiments, any or each of the connection vias 120V may include, for example, copper, nickel, stainless steel, beryllium copper, and/or a combination or any alloy thereof, but example embodiments are not limited thereto.

The semiconductor chip 200 of the semiconductor package 1000 may be disposed on the lower redistribution structure 300. The semiconductor chip 200 may be arranged in the cavity 100_C of the connection structure 100 to be apart from an inner sidewall of the cavity 100_C (for example, a sidewall of the connection structure 100 defining or at least partially defining the cavity 100_c). Although it is illustrated in FIG. 1 that the semiconductor package 1000 includes one semiconductor chip 200, the number of semiconductor chips 200 is not limited thereto.

In some example embodiments, the semiconductor chip 200 may include a logic chip and/or a memory chip. The logic chip may include, for example, a microprocessor. For example, the logic chip may include a central processing unit (CPU), a controller, and/or an application specific integrated circuit (ASIC). For example, the memory chip may include a volatile memory chip, such as a dynamic random access memory (DRAM) chip or a static RAM (SRAM) chip, and/or a non-volatile memory chip, such as a phase-change RAM (PRAM) chip, a magnetoresistive RAM (MRAM) chip, a ferroelectric RAM (FeRAM) chip, or a resistive RAM (RRAM) chip, but example embodiments are not limited thereto.

The semiconductor chip 200 may include a semiconductor substrate 210 and a chip pad 220. In some example embodiments, the semiconductor substrate 210 may include, for example, silicon (Si), but example embodiments are not limited thereto. For example, he semiconductor substrate 210 may include a semiconductor element, e.g., germanium (Ge), or a compound semiconductor, such as silicon carbide (SiC), gallium arsenide (GaAs), indium arsenide (InAs), or indium phosphide (InP).

The semiconductor substrate 210 may include an active surface and an inactive surface facing the active surface. For example, the active surface may correspond to the bottom surface of the semiconductor substrate 210, on which the chip pad 220 is arranged, and the inactive surface may correspond to the top surface of the semiconductor substrate 210, which faces the bottom surface of the semiconductor substrate 210.

The active surface of the semiconductor substrate 210 may include, for example, various kinds of individual devices. For example, the individual devices may include, but are not limited to, one or more of various microelectronic devices, e.g., a complementary metal-oxide-semiconductor (CMOS) transistor, a metal-oxide-semiconductor field effect transistor (MOSFET), a system large scale integration (LSI), an image sensor such as a CMOS imaging sensor (CIS), a micro-electro-mechanical system (MEMS), an active element, and/or a passive element.

The chip pad 220 may be arranged on the bottom surface of the semiconductor substrate 210. The chip pad 220 may be electrically connected to one or more of various kinds of individual devices included in the active surface. The chip pad 220 may also be electrically connected to at least some of lower via patterns 320V at the bottom among a plurality of lower via patterns 320V of the lower redistribution structure 300.

The lower redistribution structure 300 of the semiconductor package 1000 may extend an input/output terminal of the semiconductor chip 200 to an outer region of the semiconductor chip 200. The lower redistribution structure 300 may include a plurality of lower insulating layers 310 and the lower redistribution pattern 320.

The lower insulating layers 310 may include, but is not limited to, an insulating material, e.g., photo imageable dielectric (PID) resin. In such a case, the lower insulating layers 310 may further include an inorganic filler. Ones of lower insulating layers 310 may include, on an individual basis, the same or different materials.

The lower redistribution pattern 320 may include a lower via pattern 320V and a lower line pattern 320L. The lower line pattern 320L may be disposed on at least one of the top and bottom surfaces of each of the lower insulating layers 310. The lower via pattern 320V may be connected to a portion of the lower line pattern 320L through any or each of the lower insulating layers 310. The numbers and arrangement of lower insulating layers 310, lower via patterns 320V, and lower line patterns 320L of the lower redistribution structure 300 are not limited to those shown in the drawings and may vary according to example embodiments.

The lower redistribution pattern 320 may include, for example, a conductive material, e.g., copper (Cu), aluminum (Al), silver (Ag), tin (Sn), gold (Au), nickel (Ni), lead (Pb), titanium (Ti), or any alloy thereof, but example embodiments are not limited thereto.

The bottom surface of the semiconductor chip 200 may be in contact (for example, direct contact) with lower insulating layers 310 at the top among the lower insulating layers 310. The lower redistribution pattern 320 may extend the input/output terminal of the semiconductor chip 200 to the outside. In other words, the semiconductor package 1000 may correspond to a fan-out semiconductor package.

In some example embodiments, the lower redistribution structure 300 may be formed on the bottom surface of the semiconductor chip 200 by a chip-first process. Due to the order of forming the lower redistribution structure 300, the lower via patterns 320V may have a tapered shape having a horizontal width increasing away from the semiconductor chip 200.

In some example embodiments, the semiconductor package 1000 may further include a lower passivation layer 350. The lower passivation layer 350 may be arranged on the bottom surface of the lower redistribution structure 300 and may protect the lower redistribution structure 300. The lower passivation layer 350 may include, but is not limited to, an insulating material, e.g., thermosetting resin or thermoplastic resin.

For example, at least some of the lower line patterns 320L may be exposed by openings of (for example, defined by) the lower passivation layer 350. The exposed lower line patterns 320L may be electrically connected to lower pads 330, respectively, in the openings. External connection terminals 340 may be electrically connected to the lower pads 330, respectively.

The external connection terminals 340 may, for example, connect the semiconductor package 1000 to a main board of a separate electronic device on which the semiconductor package 1000 is mounted. The external connection terminals 340 may include a conductive material, e.g., at least one of solder, tin (Sn), silver (Ag), copper (Cu), aluminum (Al), or any alloy thereof, but example embodiments are not limited thereto. The external connection terminals 340 may have various shapes, such as, for example, a land shape, a bump shape, a pillar shape, and a fin shape, apart from a ball shape.

The molding layer 150 of the semiconductor package 1000 may be arranged to fill the space between the connection structure 100 and the semiconductor chip 200 in the cavity 100_C and may cover or at least partially cover the top surface of the connection structure 100 and the top surface of the semiconductor chip 200.

The molding layer 150 may include an epoxy-based material, a thermosetting material, a thermoplastic material, or the like. For example, the molding layer 150 may include an ABF, FR-4, BT, an epoxy molding compound (EMC), or the like, but example embodiments are not limited thereto.

The upper redistribution structure 400 of the semiconductor package 1000 may be above the connection structure 100 and the semiconductor chip 200. The upper redistribution structure 400 may include upper insulating layers 410, an upper redistribution pattern 420, an upper connection pad 430, a metal pad 440, and an upper passivation layer 450.

The upper insulating layers 410 may include, but are not limited to, an insulating material, e.g., PID resin. For example, the upper insulating layers 410 may further include an inorganic filler. The upper insulating layers 410 may individually include the same or different materials.

The upper redistribution pattern 420 may include an upper via pattern 420V and an upper line pattern 420L. The upper line pattern 420L may be disposed on at least one of the top and bottom surfaces of each of the upper insulating layers 410. The upper via pattern 420V may extend in the vertical direction (the Z direction) through the upper insulating layers 410 or the molding layer 150. The upper via pattern 420V may connect upper line patterns 420L at different vertical levels or may connect at least a portion of an upper line pattern 420L at the bottom to a connection pad 120 at the top of the connection structure 100. In some example embodiments, the upper via pattern 420V may have a tapered shape having a horizontal width increasing away (for example, when moving vertically away) from the top surface of the semiconductor chip 200. The numbers and arrangement of upper insulating layers 410, upper via patterns 420V, and upper line patterns 420L of the upper redistribution structure 400 are not limited to those shown in the drawings and may vary according to example embodiments.

In some example embodiments, the upper redistribution pattern 420 may include, for example, copper (Cu), titanium (Ti), titanium tungsten (TiW), titanium nitride (TiN), tantalum (Ta), tantalum nitride (TaN), chrome (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but example embodiments are not limited thereto.

The upper connection pad 430 may be above the top surface of an upper insulating layer 410 at the top among the upper insulating layers 410. The upper connection pad 430 may be on the upper redistribution pattern 420 and electrically connected to the upper redistribution pattern 420. For example, the upper connection pad 430 may be connected to an upper via pattern 420V at the top among a plurality of upper via patterns 420V.

The upper connection pad 430 may include a horizontal portion 431 and a vertical portion 432. The upper connection pad 430 may have a bowl shape including an inner space 430_C defined by the top surface of the horizontal portion 431 and the inner sidewall of the vertical portion 432.

The horizontal portion 431 of the upper connection pad 430 may extend in the horizontal direction (the X direction and/or the Y direction) on the upper insulating layer 410. The bottom surface of the horizontal portion 431 may be connected to the upper via pattern 420V. The horizontal portion 431 may have a sufficient horizontal width such that the metal pad 440 may be arranged in the inner space 430_C defined by the top surface of the horizontal portion 431 and the inner sidewall of the vertical portion 432. For example, a horizontal width w1 of the horizontal portion 431 may be about 340 μm. Here, the term “horizontal width” may refer to a length in the first horizontal direction (the X direction) and/or a length in the second horizontal direction (the Y direction). In other words, the “horizontal width”may refer to a horizontal radius.

The vertical portion 432 may be arranged on the horizontal portion 431 and may extend in the vertical direction (the Z direction) along the edge of the horizontal portion 431. An outer side surface of the vertical portion 432 may be coplanar with a side surface of the horizontal portion 431. The inner space 430_C of the upper connection pad 430 may be defined in a space surrounded or at least partially surrounded by the top surface of the horizontal portion 431 and the inner sidewall of the vertical portion 432. A horizontal width w2 of the vertical portion 432 may be less than the horizontal width w1 of the horizontal portion 431. For example, the width w2 of the vertical portion 432 may be about 10 μm to about 20 μm, but example embodiments are not limited thereto.

The height of the upper connection pad 430 may be less than the height of the upper passivation layer 450. In other words, a height h1 of the upper connection pad 430, i.e., the length from the bottom surface of the horizontal portion 431 to the top surface of the vertical portion 432, may be less than a height h2 of the upper passivation layer 450. Accordingly, the inner side surface, the outer side surface, and/or the top surface of the vertical portion 432 may be in contact with the upper passivation layer 450.

The upper connection pad 430 may include copper (Cu). However, example embodiments are not limited thereto, and the upper connection pad 430 may include the same material as the upper redistribution pattern 420.

The metal pad 440 may be disposed on the upper connection pad 430. The metal pad 440 may be arranged in the inner space 430_C of (for example, defined by) the upper connection pad 430 so as to be in contact with the top surface of the horizontal portion 431 of the upper connection pad 430.

The metal pad 440 may have a dual structure including a first metal pad 441 and a second metal pad 442 on the first metal pad 441. The first metal pad 441 and the second metal pad 442 may respectively include Ni and Au, but example embodiments are not limited thereto.

A horizontal width w3 of the metal pad 440 may be less than the horizontal width w1 of the horizontal portion 431 of the upper connection pad 430. For example, the horizontal width w3 of the metal pad 440 may be about 290 μm. In some example embodiments, the metal pad 440 may be arranged in, for example, an island shape in the inner space 430_C of the upper connection pad 430. In other words, the metal pad 440 may be on the horizontal portion 431 of the upper connection pad 430 to be apart from the inner side surface of the vertical portion 432 of the upper connection pad 430.

The height of the metal pad 440 may be less than the height of the vertical portion 432 of the upper connection pad 430. For example, the height of the metal pad 440 may be about 5 μm. The top surface of the metal pad 440 may be at a lower vertical level than the top surface of the upper connection pad 430 such that the metal pad 440 may be arranged in the inner space 430_C of (for example, defined by) the upper connection pad 430.

The upper passivation layer 450 may be disposed on the top surface of the upper insulating layer 410. The upper passivation layer 450 may protect the upper insulating layer 410, the upper redistribution pattern 420, the upper connection pad 430, and the metal pad 440. The upper passivation layer 450 may include, for example, an insulating material. For example, the upper passivation layer 450 may include, but is not limited to, an ABF, FR-4, BT, or an EMC.

The upper passivation layer 450 may extend in the horizontal direction (the X direction and/or the Y direction) on the upper insulating layer 410. A height h2 of the upper passivation layer 450 may be greater than the height h1 of the upper connection pad 430. For example, the height h2 of the upper passivation layer 450 may be about 14 μm. The bottom surface of the upper passivation layer 450 may be coplanar with the bottom surface of the horizontal portion 431 of the upper connection pad 430, or substantially so. The top surface of the upper passivation layer 450 may be at a higher vertical level than the top surface of the vertical portion 432 of the upper connection pad 430.

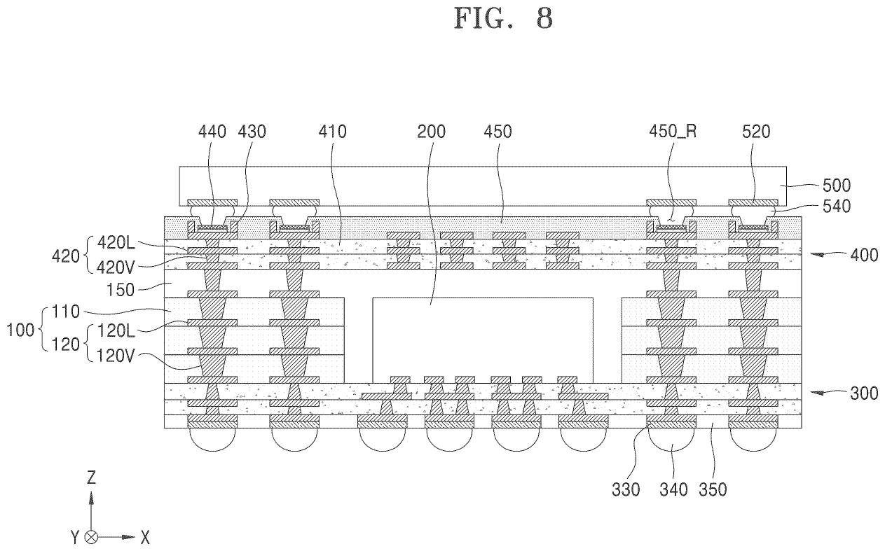

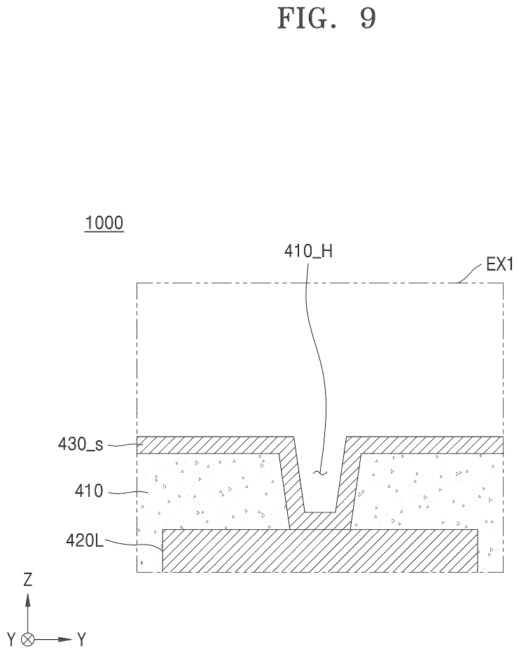

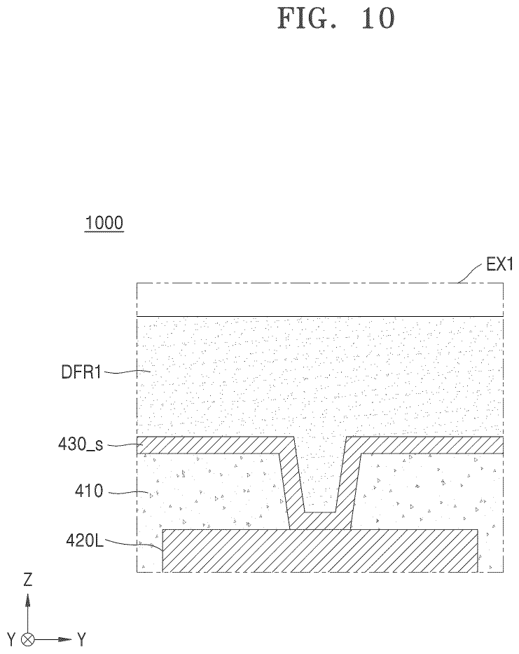

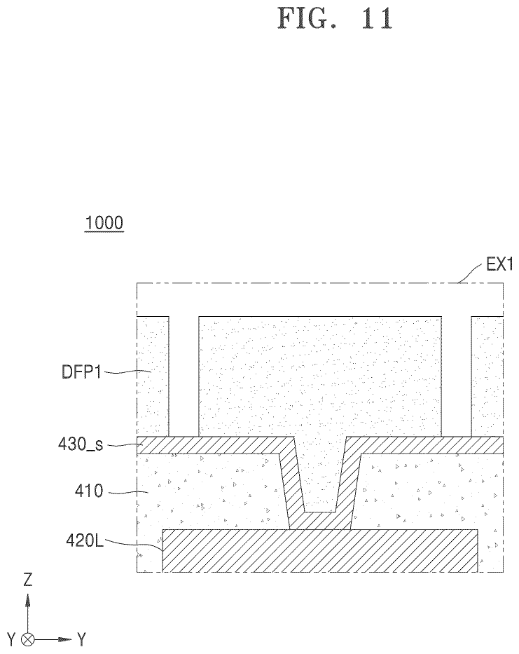

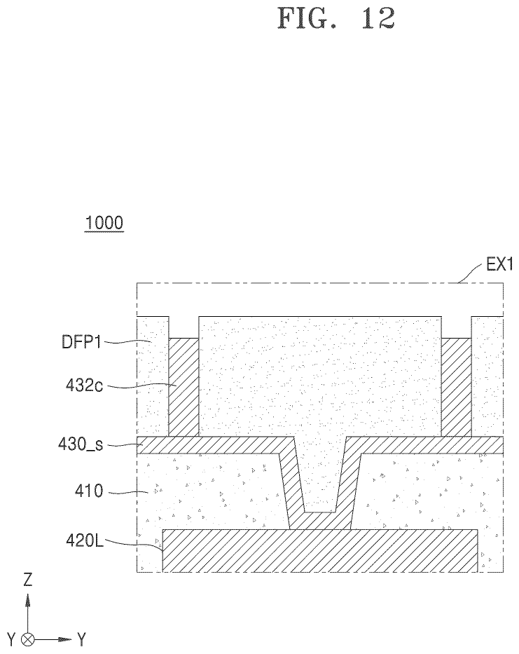

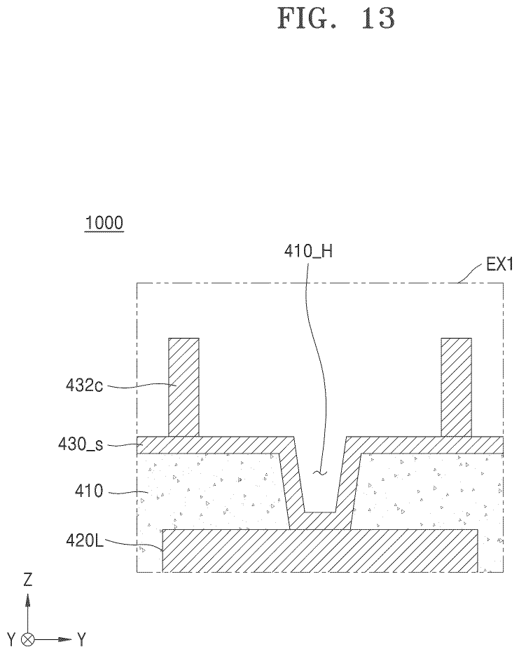

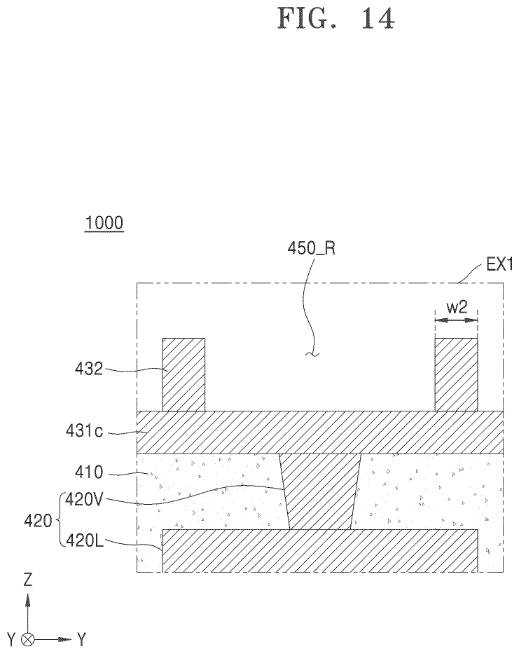

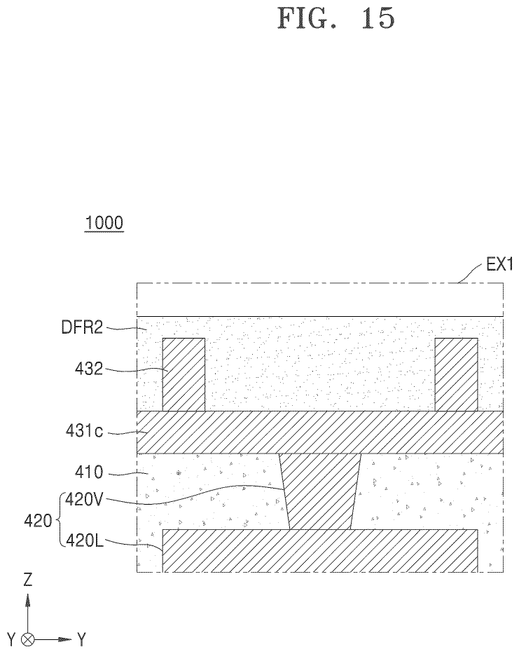

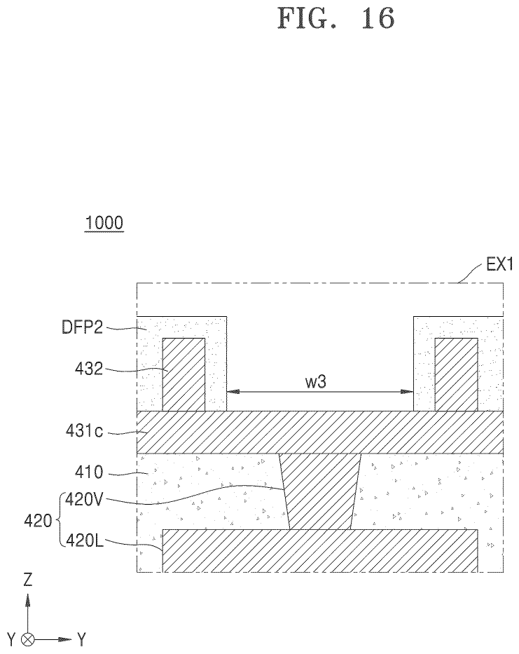

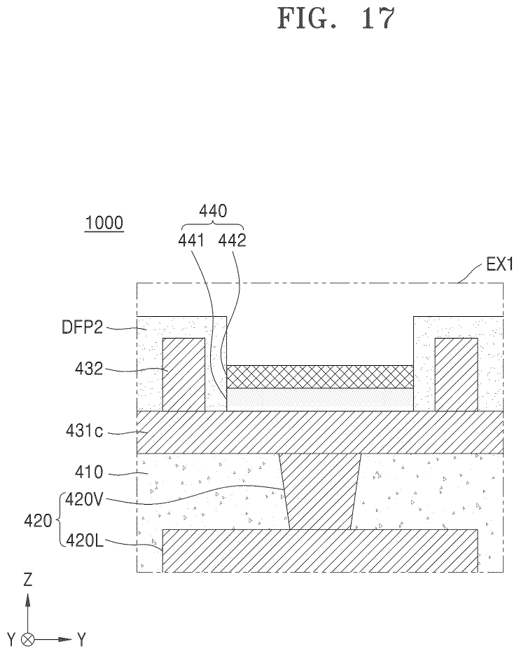

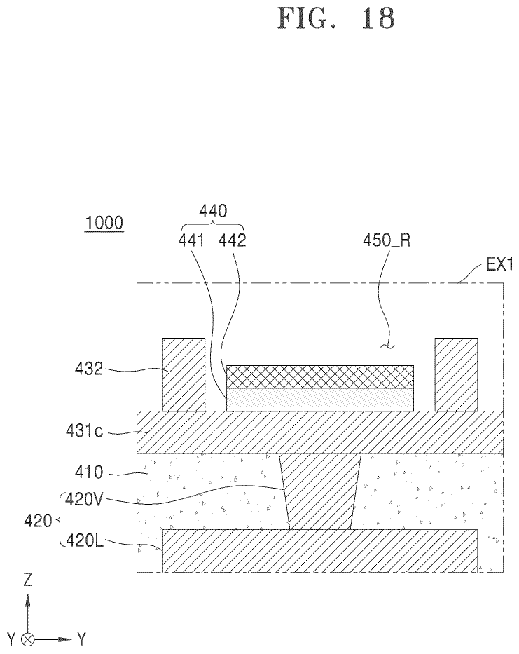

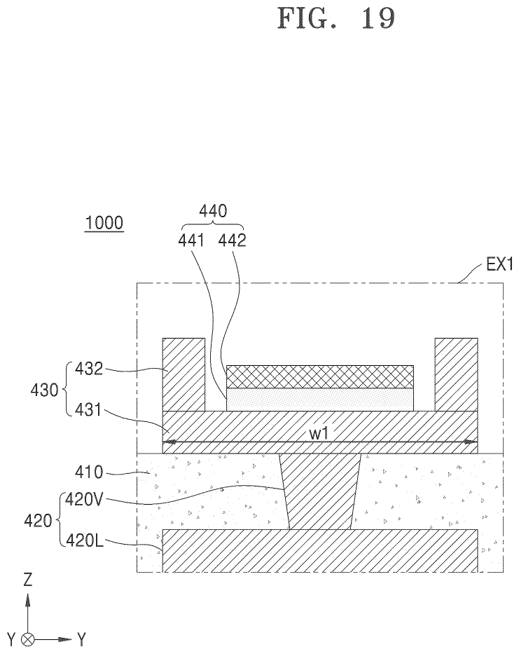

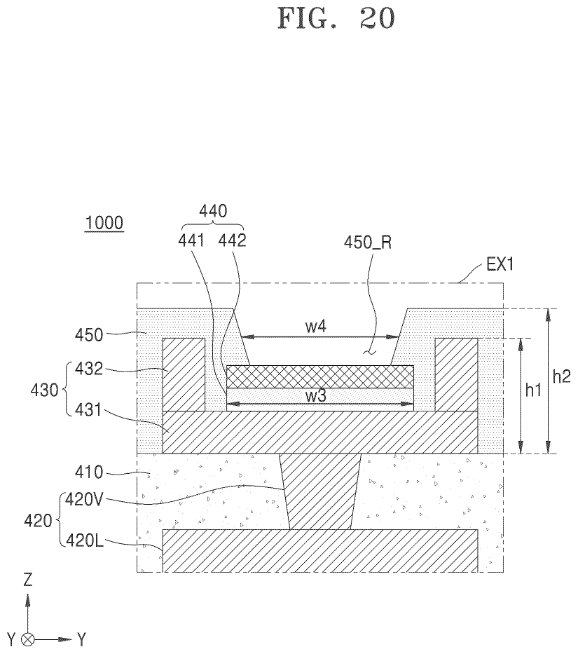

The upper passivation layer 450 may include an opening 450_R formed (for example, defined) as a portion of the upper passivation layer 450 is recessed. The opening 450_R may be formed (for example, defined) in the upper passivation layer 450 as to expose a portion of the metal pad 440. When the semiconductor package 1000 of FIGS. 1 and 2 is a lower semiconductor package of a package-on-package (PoP)-type semiconductor package, a plurality of external connection terminals 540 (in FIG. 8) connecting an upper package and a lower package, which form, for example, a PoP type semiconductor package, to each other may be arranged in the opening 450_R.

A horizontal width w4 of the opening 450_R of the upper passivation layer 450 may be less than the horizontal width w3 of the metal pad 440. The opening 450_R may be arranged on the metal pad 440 such that the edge of the metal pad 440 is covered or at last partially covered with the upper passivation layer 450. The opening 450_R may have a tapered shape having a horizontal width increasing toward the top surface of the upper passivation layer 450.

The opening 450_R may be apart from the vertical portion 432 of the upper connection pad 430 in the horizontal direction (the X direction and/or the Y direction). Accordingly, the inner side surface, the outer side surface, and the top surface of the vertical portion 432 of the upper connection pad 430 may be in contact with the upper passivation layer 450. As the upper passivation layer 450 is in contact with the three surfaces of the vertical portion 432 of the upper connection pad 430, the adhesion between the upper passivation layer 450 and the upper connection pad 430 may increase. Accordingly, even when a crack forms between the metal pad 440 and the upper passivation layer 450, the crack may be prevented or limited from progressing and leading to delamination.

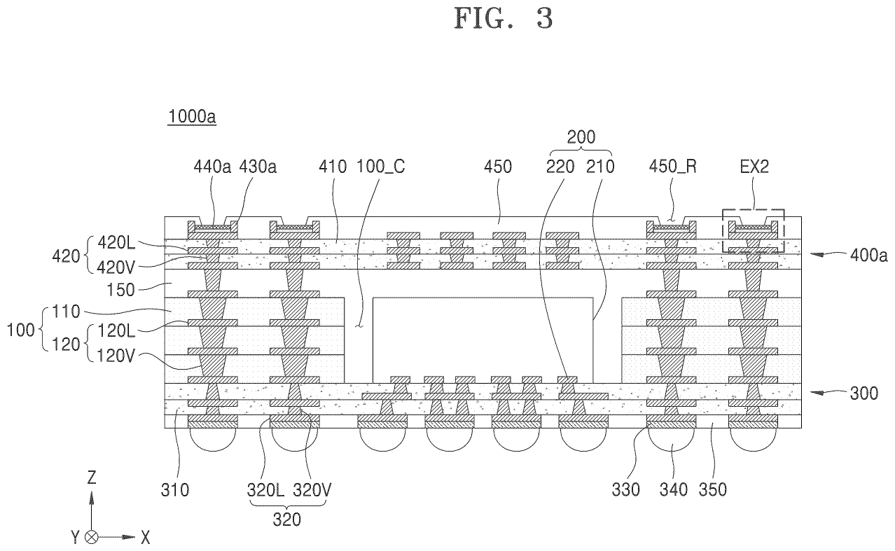

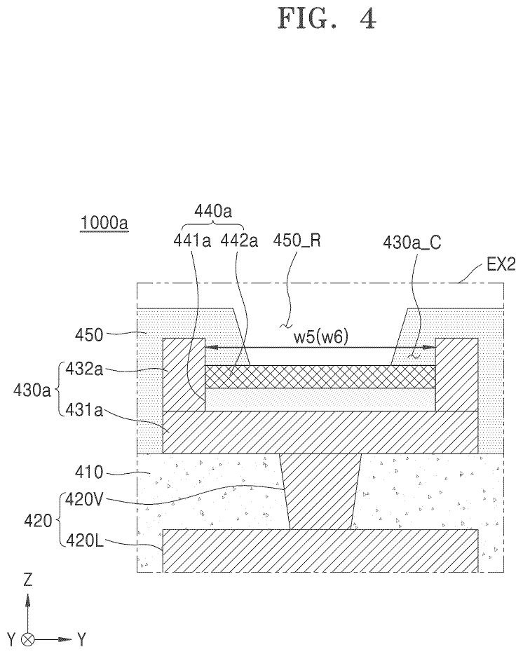

FIG. 3 is a schematic cross-sectional view of a semiconductor package 1000a according to some example embodiments. FIG. 4 is a schematic enlarged view of region EX2 in FIG. 3. The elements of the semiconductor package 1000a and the materials of the elements described below are the same or mostly and/or substantially the same as or similar to those described above with reference to FIGS. 1 and 2. Thus, for convenience of description, the differences between the semiconductor package 1000a of FIGS. 3 and 4 and the semiconductor package 1000 of FIGS. 1 and 2 are mainly described below.

Referring to FIGS. 3 and 4, the semiconductor package 1000a may include an upper redistribution structure 400a. The upper redistribution structure 400a may include an upper insulating layer 410, an upper redistribution pattern 420, an upper connection pad 430a, a metal pad 440a, and an upper passivation layer 450.

The upper connection pad 430a may be disposed on the top surface of the upper insulating layer 410. The upper connection pad 430a may be disposed on the upper redistribution pattern 420 and electrically connected to the upper redistribution pattern 420. For example, the upper connection pad 430a may be connected to an upper via pattern 420V at the top among a plurality of upper via patterns 420V.

The upper connection pad 430a may include a horizontal portion 431a and a vertical portion 432a. The upper connection pad 430a may have a bowl or similar shape including (for example defining) an inner space 430a_C defined by the top surface of the horizontal portion 431a and the inner sidewall of the vertical portion 432a.

The metal pad 440a may be disposed on the upper connection pad 430a. The metal pad 440a may be arranged in the inner space 430a_C of the upper connection pad 430a so as to be in contact with the top surface of the horizontal portion 431a of the upper connection pad 430a. The metal pad 440a may cover or at least partially over the top surface of the horizontal portion 431a of the upper connection pad 430a. A horizontal width w5 of the metal pad 440a may be the same as a horizontal width w6 of the inner space 430a_C of the upper connection pad 430a. A side surface of the metal pad 440a may be in contact with an inner side surface of the vertical portion 432a of the upper connection pad 430a.

The metal pad 440a may have a dual structure including a first metal pad 441a and a second metal pad 442a on the first metal pad 441a. The first metal pad 441a and the second metal pad 442a may respectively include Ni and Au, but example embodiments are not limited thereto.

The upper passivation layer 450 may be disposed on the top surface of the upper insulating layer 410. The upper passivation layer 450 may protect the upper insulating layer 410, the upper redistribution pattern 420, the upper connection pad 430a, and the metal pad 440a. The upper passivation layer 450 may include an opening 450_R formed as a portion of the upper passivation layer 450 is recessed. The opening 450_R may be formed in the upper passivation layer 450 to expose a portion of the metal pad 440a. The opening 450_R may be arranged on the metal pad 440a such that the edge of the metal pad 440a is covered with the upper passivation layer 450.

The opening 450_R may be apart from the vertical portion 432a of the upper connection pad 430a in the horizontal direction (the X direction and/or the Y direction). Accordingly, a portion of the inner side surface, the outer side surface, and the top surface of the vertical portion 432a of the upper connection pad 430a may be in contact with the upper passivation layer 450. As the upper passivation layer 450 is in contact with the three surfaces of the vertical portion 432a of the upper connection pad 430a, the adhesion between the upper passivation layer 450 and the upper connection pad 430a may increase.

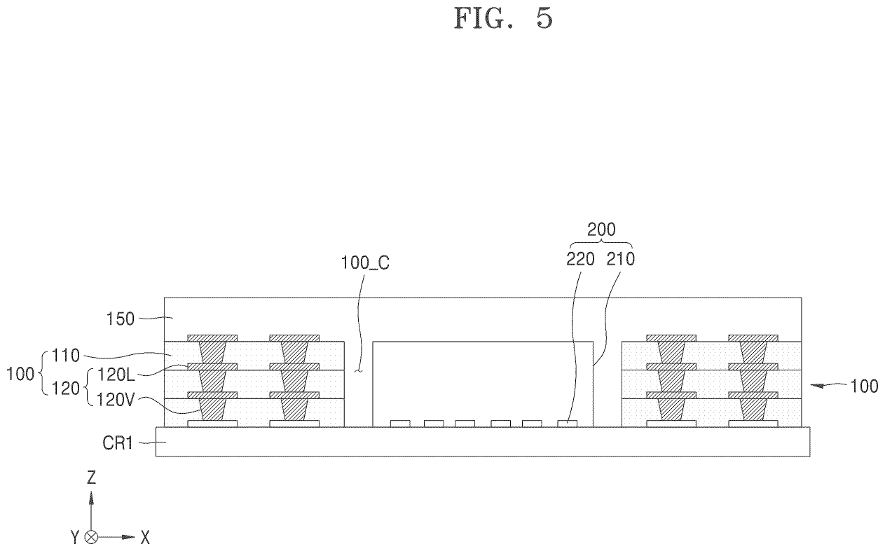

FIGS. 5 to 8 are diagrams illustrating sequential processes in a method of manufacturing a semiconductor package, according to some example embodiments.

Referring to FIG. 5, the connection structure 100 and the semiconductor chip 200 may be mounted on a first carrier substrate CR1. In some example embodiments, the connection structure 100 may have, for example, a multi-layer structure including a plurality of base layers 110 and may include a via structure 120 passing through and electrically connected to the base layers 110. The semiconductor chip 200 may be arranged in the cavity 100_C of (for example, defined by) the connection structure 100. The semiconductor chip 200 may be arranged in the cavity 100_C (for example, defined by) of the connection structure 100 such that the active surface of the semiconductor chip 200, in which a wiring structure is arranged, faces the first carrier substrate CR1.

Subsequently, the molding layer 150 may be formed to cover the connection structure 100 and the semiconductor chip 200. For example, the molding layer 150 may fill the space between the connection structure 100 and the semiconductor chip 200 in the cavity 100_C and may cover or at least partially cover the top surfaces of the connection structure 100 and the semiconductor chip 200.

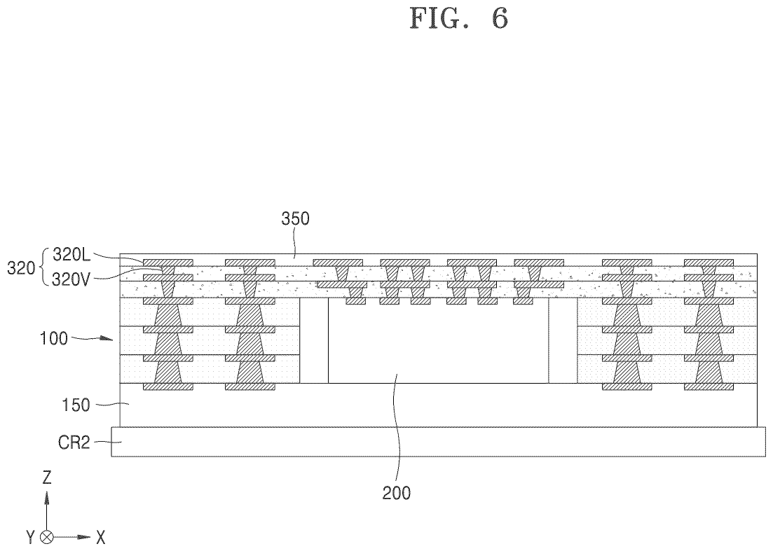

Referring to FIG. 6, the lower redistribution structure 300 may be formed on the bottom surfaces of the connection structure 100 and the semiconductor chip 200.

The resultant structure of FIG. 5 may be flipped and mounted on a second carrier substrate CR2 such that one surface of the molding layer 150 is in contact with the second carrier substrate CR2, and then the first carrier substrate CR1 may be removed.

Subsequently, lower insulating layers 310 and the lower redistribution pattern 320, in which lower via patterns 320V and lower line patterns 320L are alternately formed, may be formed on the connection structure 100 and the semiconductor chip 200 by using a redistribution process. In some example embodiments, to protect a portion of the lower redistribution pattern 320, the lower passivation layer 350 may be formed on the lower insulating layers 310.

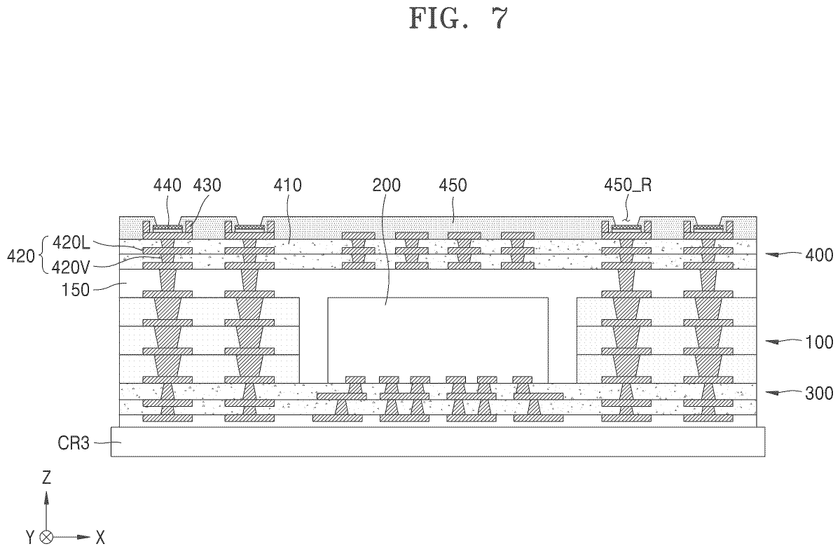

Referring to FIG. 7, the upper redistribution structure 400 may be formed above the connection structure 100, the semiconductor chip 200, and the molding layer 150.

The resultant structure of FIG. 6 may be flipped and mounted on a third carrier substrate CR3 such that one surface of the lower redistribution structure 300 is in contact with the third carrier substrate CR3, and then the second carrier substrate CR2 may be removed.

Subsequently, upper insulating layers 410 and the upper redistribution pattern 420, in which upper via patterns 420V and upper line patterns 420L are alternately formed, may be formed on the connection structure 100, the semiconductor chip 200, and the molding layer 150 by using, for example, a redistribution process. The upper connection pad 430 and the metal pad 440 may be formed on the upper redistribution pattern 420.

Thereafter, the upper passivation layer 450 may be formed on the upper insulating layers 410. The opening 450_R may be formed in an upper portion of the upper passivation layer 450 to expose a portion of the metal pad 440. A method of manufacturing the upper connection pad 430, the metal pad 440, and the upper passivation layer 450 is described in detail below.

Referring to FIG. 8, external connection terminals 340 may be formed on the lower redistribution structure 300, and the third carrier substrate CR3 may be removed.

An upper semiconductor package 500 may be mounted on the upper redistribution structure 400. An upper connection terminal 540 may be formed on a lower pad 520 of the upper semiconductor package 500. Thereafter, the upper connection terminal 540 may be located in the opening 450_R of the upper passivation layer 450 to electrically connect the upper semiconductor package 500 to the metal pad 440.

FIGS. 9 to 20 are enlarged views of region EX1 of the semiconductor package 1000 of FIG. 1 in sequential processes in a method of manufacturing the semiconductor package 1000. FIGS. 9 to 20 illustrate processes of manufacturing the upper connection pad 430, the metal pad 440, and the upper passivation layer 450.

Referring to FIGS. 9 and 10, a metal seed layer 430_s may be formed along the top surface of an upper insulating layer 410 and a through hole 410_H, which are formed on an upper line pattern 420L, and a photoresist layer DFR1 may be formed on the metal seed layer 430_s. For example, the photoresist layer DFR1 may include, but not limited to, a dry film photoresist composition.

Referring to FIG. 11, a photoresist pattern DFP1 may be formed by performing photolithography on the resultant structure of FIG. 10 by using the photoresist layer DFR1 (see FIG. 10). An opening may be formed in the photoresist pattern DFP1. The opening may correspond to a region in which the vertical portion 432 of the upper connection pad 430 in FIG. 2 is formed.

Referring to FIGS. 12 and 13, a vertical base 432c may be formed in the resultant structure of FIG. 11. For example, by performing a plating process using the metal seed layer 430_s, the vertical base 432c may be formed in a portion exposed by the photoresist pattern DFP1. For example, the plating process may include electroless plating or electroplating. After the plating process, the photoresist pattern DFP1 may be removed.

Referring to FIG. 14, a plating process may be further performed on the resultant structure of FIG. 13. The upper via pattern 420_V may be formed by filling the metal seed layer 430_s in the through hole 410_H through the plating process. Through the plating process, a horizontal base 431c may also be formed. The horizontal base 431c may be a portion which will become the horizontal portion 431 (see FIG. 2) of the upper connection pad 430 (see FIG. 2). The plating process may be performed such that the horizontal base 431c has a thickness required, desired, and/or advantageous for the horizontal portion 431. The vertical base 432c (see FIG. 12) may form the vertical portion 432, which has a required, desired, and/or advantageous horizontal width and height, through the plating process. For example, the horizontal width w2 of the vertical portion 432 may be about 10 μm to about 20 μm.

Referring to FIGS. 15 and 16, a photoresist layer DFR2 may be formed on the horizontal base 431c and the vertical portion 432, and a photoresist pattern DFP2 may be formed by performing photolithography on the photoresist layer DFR2. An opening may be formed in the photoresist pattern DFP2. The opening of the photoresist pattern DFP2 may be formed on the horizontal base 431c to be apart from the inner side surface of the vertical portion 432. The opening of the photoresist pattern DFP2 may be formed to have a horizontal width corresponding to the horizontal width w3 of the metal pad 440 (in FIG. 2).

Referring to FIG. 17, the metal pad 440 may be formed on the resultant structure of FIG. 16. For example, by performing a plating process, the metal pad 440 may be formed on the horizontal base 431c exposed by the photoresist pattern DFP2. The metal pad 440 may be formed to be apart from the inner side surface of the vertical base 432c according to the position of the opening of the photoresist pattern DFP2. The metal pad 440 may include the first metal pad 441 and the second metal pad 442, which are sequentially stacked on the horizontal base 431c. For example, the first metal pad 441 may include, for example, nickel (Ni), and the second metal pad 442 may include metal including gold (Au), but example embodiments are not limited thereto.

Referring to FIGS. 18 and 19, the photoresist pattern DFP2 may be removed from the resultant structure of FIG. 17, and the horizontal portion 431 having the horizontal width w1 may be formed by removing a portion of the horizontal base 431c. For example, the horizontal width w1 of the horizontal portion 431 may be about 340 μm. The side surface of the horizontal portion 431 may be coplanar with the outer side surface of the vertical portion 432. The horizontal portion 431 and the vertical portion 432 may form the upper connection pad 430 having, for example, a bowl or similar shape, but example embodiments are not limited thereto.

Referring to FIG. 20, the upper passivation layer 450 may be formed on the top surface of the upper insulating layer 410 in the resultant structure of FIG. 19. The upper passivation layer 450 may be formed to have the height h2 that is greater than the height h1 of the upper connection pad 430. The top surface of the upper passivation layer 450 may be at a higher vertical level than the top surface of the vertical portion 432 of the upper connection pad 430.

The opening 450_R may be formed in the upper passivation layer 450 to expose a portion of the metal pad 440. The opening 450_R may be, for example, formed not to extend beyond the metal pad 440. The horizontal width w4 of the opening 450_R may be less than the horizontal width w3 of the metal pad 440. The upper passivation layer 450 may be formed to cover the upper insulating layer 410, the upper connection pad 430, and a portion of the metal pad 440. The upper passivation layer 450 may be formed to be in contact with the inner side surface, the outer side surface, and the top surface of the vertical portion 432 of the upper connection pad 430.

While the inventive concepts have been particularly shown and described with reference to example embodiments thereof, it will be understood by one of ordinary skill in the art that various changes in form and details may be made therein without departing from the spirit and scope of the following claims.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or”includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package comprising:
a lower redistribution structure;
a connection structure on the lower redistribution structure and defining a cavity;
a semiconductor chip on the lower redistribution structure and in the cavity defined by the connection structure; and
an upper redistribution structure above the connection structure and the semiconductor chip and electrically connected to the connection structure,
wherein the upper redistribution structure includes
an upper insulating layer and an upper redistribution pattern;
an upper connection pad on a top surface of the upper insulating layer, the upper connection pad being electrically connected to the upper redistribution pattern, including a horizontal portion and a vertical portion, and having a bowl shape;
a metal pad on the horizontal portion of the upper connection pad and apart from an inner side surface of the vertical portion of the upper connection pad; and
an upper passivation layer on the top surface of the upper insulating layer and defining an opening exposing a portion of the metal pad.

2. The semiconductor package of claim 1, wherein
the vertical portion of the upper connection pad extends in a vertical direction on an edge of the horizontal portion of the upper connection pad,
an inner space is defined by the inner side surface of the vertical portion of the upper connection pad and a top surface of the horizontal portion of the upper connection pad, and
the metal pad is in the inner space.

3. The semiconductor package of claim 1, wherein a horizontal width of the metal pad is less than a horizontal width of the horizontal portion of the upper connection pad.

4. The semiconductor package of claim 1, wherein a top surface of the vertical portion of the upper connection pad is at a higher vertical level than a top surface of the metal pad.

5. The semiconductor package of claim 1, wherein a height of the upper passivation layer is greater than a height of the upper connection pad.

6. The semiconductor package of claim 1, wherein a top surface of the upper passivation layer is at a higher vertical level than a top surface of the vertical portion of the upper connection pad.

7. The semiconductor package of claim 1, wherein a bottom surface of the upper passivation layer is coplanar with a bottom surface of the horizontal portion of the upper connection pad.

8. The semiconductor package of claim 1, wherein the upper passivation layer at least partially surrounds an inner side surface, an outer side surface, and a top surface of the vertical portion of the upper connection pad.

9. The semiconductor package of claim 1, wherein the metal pad includes a first metal pad and a second metal pad, the second metal pad on the first metal pad.

10. The semiconductor package of claim 9, wherein
the first metal pad and the second metal pad include different materials from each other,
the first metal pad includes nickel (Ni) and the second metal pad includes gold (Au).

11. The semiconductor package of claim 1, wherein the opening defined by the upper passivation layer is on the metal pad and apart from an inner side surface of the vertical portion of the upper connection pad.

12. The semiconductor package of claim 1, wherein a horizontal width defined by the opening of the upper passivation layer is less than a horizontal width of the metal pad.

13. The semiconductor package of claim 1, wherein the upper passivation layer at least partially covers an edge of a top surface of the metal pad.

14. The semiconductor package of claim 1, wherein a horizontal width of the vertical portion of the upper connection pad is 10 μm to 20 μm.

15. The semiconductor package of claim 1, wherein the opening defined by the upper passivation layer is defined to have a tapered shape having a horizontal width that increases when moving vertically away from a top surface of the upper redistribution structure.

16. A semiconductor package comprising:
a lower redistribution structure;
a connection structure on the lower redistribution structure and defining a cavity, the connection structure including a via structure;
a semiconductor chip on the lower redistribution structure and in the cavity defined by the connection structure;
a molding layer at least partially filling a space defined between the connection structure and the semiconductor chip, in the cavity; and
an upper redistribution structure on the molding layer, above the connection structure and the semiconductor chip, and electrically connected to the connection structure,
wherein the upper redistribution structure includes
an upper insulating layer and an upper redistribution pattern;
an upper connection pad on a top surface of the upper insulating layer and electrically connected to the upper redistribution pattern, the upper connection pad including a horizontal portion and a vertical portion, the vertical portion extending in a vertical direction on an edge of the horizontal portion, the upper connection pad having a bowl shape, an inner side surface of the vertical portion and a top surface of the horizontal portion defining an inner space;
a metal pad in the inner space and on the top surface of the horizontal portion so as to be apart from the inner side surface of the vertical portion, the metal pad including a first metal pad and a second metal pad, the second metal pad on the first metal pad; and
an upper passivation layer on the top surface of the upper insulating layer, the upper passivation layer defining an opening exposing a portion of the metal pad and having a horizontal width less than a horizontal width of the metal pad,
wherein the upper passivation layer at least partially surrounds
the inner side surface of the upper connection pad,
an outer side surface of the upper connection pad, and
a top surface of the vertical portion of the upper connection pad.

17. A semiconductor package comprising:
a lower redistribution structure;
a connection structure on the lower redistribution structure and defining a cavity;
a semiconductor chip on the lower redistribution structure and in the cavity defined by the connection structure; and
an upper redistribution structure above the connection structure and the semiconductor chip and electrically connected to the connection structure,
wherein the upper redistribution structure includes
an upper insulating layer and an upper redistribution pattern;
an upper connection pad on a top surface of the upper insulating layer, the upper connection pad being electrically connected to the upper redistribution pattern, including a horizontal portion and a vertical portion, and having a bowl shape;
a metal pad on the horizontal portion of the upper connection pad and in contact with an inner side surface of the vertical portion of the upper connection pad; and
an upper passivation layer arranged on the top surface of the upper insulating layer and defining an opening exposing a portion of the metal pad.

18. The semiconductor package of claim 17, wherein
the vertical portion of the upper connection pad extends in a vertical direction on an edge of the horizontal portion of the upper connection pad,
an inner space is defined by the inner side surface of the vertical portion of the upper connection pad and a top surface of the horizontal portion of the upper connection pad, and
the metal pad is in the inner space.

19. The semiconductor package of claim 17, wherein a height of the upper passivation layer is greater than a height of the upper connection pad.

20. The semiconductor package of claim 17, wherein the opening defined by the upper passivation layer exposes the metal pad and is apart from an inner side surface of the vertical portion of the upper connection pad.
